(19) United States
(12) Patent Application Publication
(10) Pub. No.: US 2020/0225642 A1
(43) Pub. Date: Jul. 16, 2020

(54) Method For Controlling A Machine Tool And Machine Tool

(71) Applicant: SIG SAUER GmbH, Eckernforde (DE)

(72) Inventors: Arndt GORTZ, Schwedeneck (DE); Sven LAUSEN, Eckernforde (DE)

(21) Appl. No.: 16/737,890

(22) Filed: Jan. 8, 2020

(30) Foreign Application Priority Data
Jan. 10, 2019 (DE) 102019100474.8

(51) Int. Cl. G05B 19/414; G05B 19/18; G05B 19/19; G06F 30/10

(52) U.S. Cl. CPC G05B 19/4145; G06F 30/10; G05B 19/19; G05B 19/182

(57) ABSTRACT

A method for controlling a machine tool is presented. The method include: providing a machine tool; providing a manufacturing sequence of multiple manufacturing steps; generating control data with control commands that specify machining operations of the machine tool according to the manufacturing steps of the manufacturing sequence, and additional data which includes at least one list which specifies parameters extracted from the control commands; providing the control data in a control unit of the machine tool; receiving input data in the control unit, where the input data specifies a user input; generating modified control commands by way of the control unit, such that the modified control commands are generated from the control commands in accordance with the additional data and the input data; and actuating the machine tool by the control device in accordance with the modified control commands.

### BACKGROUND

Machine tools are often used to manufacture components. On machine tools with a CNC controller, manufacturing steps are described in a program. The controller of the machine tool then executes this program to manufacture the workpiece. If the program consists of a few instructions, it can be written directly in the programming language of the machine by a machine operator or setter.

In particular for complex components, it is known that the program is created either with graphical support on the machine tool or by computer-aided manufacturing (CAM) software. In this software, 2D and 3D data of the workpieces to be manufactured can be read in to support the programmer in creating the program.

Furthermore, multiple clamping systems are known for better utilising the available machine capacity. Multiple clamping nests are thus built on in the working region in order to be able to manufacture multiple components without the machine operator having to reclamp components. As a result, run times of the programs can be increased, and one operator can operate multiple machines simultaneously.

If the clamping nests are built on pallets, and these pallets are additionally changed by the machine tool, a supply of workpieces to be manufactured can be prepared, which are processed step by step by the machine without any intervention by the operator.

All these developments mean that the tasks of the machine setter and machine operator have become very complex.

For instance, it can be necessary for the setter, when setting up a new program, to first bring the zero points, which the programmer has made according to ideal specifications, into correspondence with the real position on the machine. If the machine tool has more than three shafts, for example via an additional rotary shaft, a zero point can be defined for each clamping nest and each angular position of the shaft. If there is a four-sided clamping tower with three nests per side, there are thus 36 zero points for three angular positions. Tool paths can be programmed at each zero point, and each tool path can be assigned a tool which can correspond to or differ from the tool of a previous machining process.

When the setter prepares a manufacturing process, it can thus be necessary to check both the zero points and the tool paths and adjust them if necessary. This can require an iterative process in which first a first clamping position is processed in full and corrected if necessary. If a correction was necessary, previous parts may not be usable for a subsequent clamping process, otherwise errors could be transferred to the subsequent clamping position. In this case, the first clamping position must be produced again. This process can be repeated for all clamping positions.

To accelerate this process, it is known to integrate jump labels in the NC program so that unnecessary program parts can be skipped. With complex programs, errors can occur here, for example if tool change does not take place before each programmed tool path but only before the first tool path which uses the tool in question. In this case, all the machining processes except for the commands necessary for the tool retrieval would have to be skipped. In this case, a repeated adjustment of jump labels can be necessary for each step of the manufacturing preparation process. As an alternative to this procedure, it is known to carry out “dry runs”, in which a workpiece is machined only on one clamping nest and all the other clamping nests are empty. In such a procedure, the entire program is executed, and the tool in question moves through the air instead of through a workpiece at empty clamping nests.

If a machine tool with changing pallets is used, it can be necessary to make adjustments for each pallet. In this case, copies of the programs can be applied and stored separately for each pallet. If there are changes to the program, a new program without changes can be created first. If there are changes to a program, it can be necessary to carry out preparations again for parts of the program or the entire program.

### SUMMARY

The object of the invention is to provide a method for controlling a machine tool and a machine tool with which improved technologies are provided for actuating machine tools with efficient and convenient operation.

The object is achieved by a method for controlling a machine tool according to independent

claim 1 and by a machine tool according to the further independent claim 15. Embodiments form the subject matter of dependent claims.

According to one aspect, a method for controlling a machine tool is created. The method comprises: providing a machine tool; providing a manufacturing sequence comprising multiple manufacturing steps, at least one tool and one tool path being defined for each manufacturing step; and generating control data. The control data comprise control commands and additional data, the control commands specifying machining operations of the machine tool according to the manufacturing steps of the manufacturing sequence, and the machine tool being configured to convert the control commands into the machining operations, and the additional data comprising at least one list which specifies parameters extracted from the control commands. The method further comprises: providing the control data in a control unit of the machine tool; receiving input data in the control unit, the input data specifying a user input; generating modified control commands by means of the control unit, the modified control commands being generated from the control commands in accordance with the additional data and the input data; and actuating the machine tool by the control device by means of the modified control commands.

According to a further aspect, a machine tool is created which comprises a control device. The control device is configured to provide control data. The control data comprise control commands and additional data. The control commands specify machining operations of the machine tool corresponding to manufacturing steps of a manufacturing sequence, the manufacturing sequence comprising multiple manufacturing steps, and at least one tool and one tool path being defined for each manufacturing step, and the machine tool being configured to convert the control commands into the machining operations. The additional data comprise at least one list which specifies parameters extracted from the control commands. The control device is also configured to receive input data which specify a user input, to generate modified control commands from the control commands corresponding to the additional data and the input data, and to actuate the machine tool by means of the modified control commands.

A tool path within the meaning of the disclosure can be the definition of one or more individual points, for example coordinates for one or more bores. Further definitions can be provided for the manufacturing steps. For the manufacturing steps, manufacturing parameters can be defined, for example the advancing speed, rotation speed, rotation direction, at least one depth of cut and/or the number of passes along the tool path. There can be different combinations of definitions for different manufacturing steps. For example, a tool and a tool path can be defined for all manufacturing steps, whereas a drilling depth and a drilling cycle are specified for a drilling manufacturing step, and a depth of cut and an advancing speed are specified instead of a drilling depth and a drilling cycle for a milling manufacturing step.

The generation of modified control commands can comprise the generation of a data set or a file which comprises the modified control commands. Alternatively or additionally, the generation of modified control commands can comprise the retrieval of control commands and optionally the modification of retrieved control commands without a complete set of modified control commands being generated. For example, the generation of modified control commands and the actuation of the machine tool by means of the modified control commands can comprise the sequential retrieval and optionally modification of control commands and the direct actuation of the machine tool according to the retrieved and optionally modified control command in question, the modified control commands corresponding to a modified manufacturing sequence and being available in a memory consecutively, but at no point as a complete set of modified control commands. In a further example, a complete set of modified control commands can be generated first and then control commands of the set of modified control commands can be retrieved sequentially and optionally modified or modified again, and the machine tool can be actuated directly corresponding to the control command retrieved and optionally modified or modified again.

The manufacturing sequence can be provided as a manufacturing data set in an external computer unit. For example, the manufacturing data set can comprise a CAM file or a CAM program. The external computer unit can be a computer, and the provision of the manufacturing data set can comprise the generation of a CAM file by means of a CAM environment on the computer.

Alternatively, the manufacturing sequence can be provided in the machine tool, for example as a manufacturing data set. For example, the manufacturing sequence can be entered at an operating terminal of the machine tool. The manufacturing sequence can be provided in the control unit of the machine tool.

The control commands can be generated in the external computer unit from the manufacturing data set. For example, a post-processor which generated control commands from the CAM file can be provided in the external computer unit. The control commands can be, for example, an NC code, DIN/ISO programming and/or a G code.

Alternatively, the control commands can be generated in the machine tool, for example in the control unit. The control commands can be generated from the manufacturing data set, for example by means of a post-processor in the machine tool. In this case, the manufacturing data set can be generated in the machine tool or outside the machine tool and provided in the machine tool.

As a further alternative, the control commands can be entered at an operating terminal of the machine tool, for example as an input of a G code. In this case, the manufacturing sequence can be provided in the machine tool in the form of the control commands.

The additional data can be generated in the external computer unit. Alternatively, the additional data can be generated in the machine tool, for example in the control unit. As a further alternative, a further external computer unit can be provided, in which the additional data are generated. For example, the further external computer unit can be provided as a server on which manufacturing data sets and/or control commands are stored for provision on machine tools.

The generation of the control data and the generation of the additional data can take place in the same or in different devices (machine tool, external computer unit and further external computer unit).

The additional data can be generated by means of a post-processor, for example during or after the generation of the control data by means of the post-processor.

The generation of the control data can take place by combining the control commands and the additional data, for example by storing them together in a memory and/or by providing them together in a processor. The generation of the control can take place in the machine tool, the external computer unit or the further external computer unit.

The input data can be received in the control unit from an input device of the machine tool. The input device can comprise, for example, switches, keys (for example a keyboard), a touchscreen, a mouse or a tracking ball and/or touchpad.

The input data can be received in the control unit from an input device of a portable operating device via a transmitting unit of the portable operating device and a receiving unit of the machine tool. The portable operating device can be, for example, a mobile telephone (smartphone), a tablet computer or a laptop computer. For example, a software application (app) can be provided on the portable operating device, and the input data can be sent to the machine tool by means of the software application via an input device of the portable operating device, for example a touchscreen of a smartphone. The transfer of the input data can take place in a wireless or wired manner. For example, the transmitting unit of the portable operating device and the receiving unit of the machine tool can be configured for wireless transfer of the input data, for example via a wireless network (WLAN), a mobile radio network, Bluetooth, an infrared link and/or another wireless data link.

The parameters extracted from the control commands can specify the manufacturing steps of the manufacturing sequence, and the input data can comprise a command to start machining operations by the machine tool after a previous interruption of machining operations according to the control commands. In this case, the generation of modified control commands can comprise the deletion of control commands which correspond to manufacturing steps of the manufacturing sequence which were completed before the interruption of machining operations, and at least one of the addition of a control command and the addition of a command parameter for a control command such that, when machining operations start, machining takes place as if no previous interruption of machining operations has taken place.

For example, during performance of machining operations, monitoring of completed machining operations can take place so that it can be determined, when the input data are received, which machining operations were completed prior to the interruption of machining operations according to the control commands. The additional data can comprise a list of the manufacturing steps of the manufacturing sequence extracted from the control commands, and starting parameters associated therewith. The starting parameters can be, for example, a return plane before the start of a relevant manufacturing step, a tool for the relevant manufacturing step, the position before the start of the relevant manufacturing step and/or a manufacturing parameter, for example a rotation speed or advance, for the relevant manufacturing step. When the input data, comprising a command for the start of machining operations by the machine tool after a previous interruption of machining operations, are received, the last completed machining step can be determined. The generation of modified control commands can then take place such that the modified control commands specify the start of machining at a machining step following the last completed machining step, in that all the previous control commands are removed; compliance with the starting parameters of the machining step following the last completed machining step is ensured by adding at least one control command or a command parameter for a control command. For example, a control command for changing in a tool and/or for moving to a return plane or a position before the first control command of the machining step following the last completed machining step can be inserted. Alternatively or additionally, one or more command parameters can be added to one control command of the machining step following the last completed machining step. For example, a command parameter for specifying a tool to be used and/or a manufacturing parameter can be added to a first control command of the machining step following the last completed machining step. Such a command parameter cannot be defined in a corresponding control command of the control data because it is unchanged in comparison with a previous control command. With the addition of the relevant command parameter to the control command of the modified control data, correct machining can thus be ensured.

In general, the deletion of control commands in examples in which the generation of modified control commands comprises the sequential retrieval and optionally modification of control commands and the direct actuation of the machine tool can comprise skipping the control commands to be deleted during the sequential retrieval of the control commands.

The parameters extracted from the control commands can specify multiple zero points which are each assigned to at least one manufacturing step of the manufacturing sequence, and the input data can comprise a command to start machining operations by the machine tool. In this case, the generation of modified control commands can comprise checking whether correction data exist for each of the zero points, the correction data specifying a deviation of an actual position of the zero point in question from an ideal position of the zero point in question defined in the manufacturing sequence, and, if no correction data exist for the zero points, determining correction data for each zero point, and changing command parameters of the control commands corresponding to the correction data such that the modified control commands effect a correct actuation of the machine tool according to the manufacturing sequence for the respective actual positions of the zero points.

For example, the zero points can be assigned to different clamping operations or clamping nests which are to be machined by the machine tool within a working cycle. In this case, the control commands each specify a (theoretical) zero point for a manufacturing step or a group of manufacturing steps, which correspond to a clamping operation or a clamping nest. The correction data then specify a respective deviation of a real position of the corresponding zero points in a clamping operation from the theoretical position of the corresponding zero point. The changing of command parameters of the control commands can comprise, for example, the changing of coordinates, for example machine coordinates, in the control commands, for example in a G code, the coordinates being changed such that the modified control commands specify tool paths in relation to a real zero point, which correspond to tool paths specified by the control commands in relation to the corresponding theoretical zero point. If, for example, a real zero point is shifted by 0.1 mm in the direction of an X axis relative to a corresponding theoretical zero point, the generation of modified control commands can comprise adding 0.1 mm to all X coordinates in control commands relating to the theoretical zero point in question.

The correction data can be stored in a corresponding log file, for example in the machine tool. If new correction data are determined, existing correction data, for example one or more existing log files, can be deleted.

The determination of the correction data can comprise the activation of measurement cycles of the machine tool. For example, in response to determining that no correction data exist for the zero points, measurement cycles of the machine tool can be automatically retrieved, which measure the corresponding real zero points and compare them with the theoretical zero points in order to generate corresponding correction data. Alternatively, in response to determining that no correction data exist for the zero points, output data can be generated, by means of which a user of the machine tool is requested to measure the real zero points, for example by starting corresponding measurement cycles of the machine tool.

The parameters extracted from the control commands can specify the manufacturing steps of the manufacturing sequence, and the input data can comprise a command for deactivating a manufacturing step to be deactivated in the manufacturing sequence. In this case, the generation of modified control commands can comprise the deletion of control commands which correspond to the manufacturing step to be deactivated. The generation of modified control commands can in this case additionally comprise at least one of the addition of a control command and the addition of a command parameter for a control command such that, at the start of a manufacturing step following a manufacturing step to be deactivated, machining takes place as if the manufacturing step to be deactivated is not deactivated. In this case, the embodiments explained in connection with the start of machining operations by the machine tool after a previous interruption of machining operations can be provided accordingly.

In addition, the reactivation of a deactivated manufacturing step can be provided such that the input data comprise a command for reactivating a deactivated manufacturing step of the manufacturing sequence, and the generation of modified control commands comprises the addition of previously deleted control commands which correspond to the manufacturing step to be reactivated. It can be provided for any manufacturing steps of the manufacturing sequence to be deactivated and/or reactivated by means of corresponding input data.

Alternatively or additionally, it is possible to provide the simultaneous deactivation and/or reactivation of all control commands for a manufacturing step or a group of manufacturing steps which are defined in relation to a zero point which can specify a clamping operation or a clamping nest. In this case, the embodiments explained in connection with the deactivation and/or reactivation of a manufacturing step can be provided accordingly.

The parameters extracted from the control commands can specify the manufacturing steps of the manufacturing sequence and functions associated with the respective manufacturing steps, and the input data can comprise a command for deactivating a function to be deactivated of a manufacturing step of the manufacturing sequence. In this case, the generation of modified control commands can comprise the deletion of control commands which correspond to the function to be deactivated of the manufacturing step. The generation of modified control commands can in this case additionally comprise at least one of the addition of a control command and the addition of a command parameter for a control command such that, when a control command following a function to be deactivated is retrieved, machining takes place as if the function to be deactivated is not deactivated. In this case, the embodiments explained in connection with the start of machining operations by the machine tool after a previous interruption of machining operations can be provided accordingly.

The function to be deactivated can be, for example, a tool breakage check at the start and/or after the completion of the corresponding manufacturing step, and the corresponding control commands can specify a measurement cycle for tool lengths.

In addition, the reactivation of a deactivated function can be provided such that the input data comprise a command for reactivating a deactivated function, and the generation of modified control commands comprises the addition of previously deleted control commands which correspond to the function to be reactivated. In this case, the embodiments explained in connection with the deactivation and reactivation of manufacturing steps can be provided accordingly.

The parameters extracted from the control commands can specify the manufacturing steps of the manufacturing sequence and the manufacturing parameters associated with the respective manufacturing steps, and the input data can comprise a command for changing a manufacturing parameter to be changed of a manufacturing step of the manufacturing sequence. In this case, the generation of modified control commands can comprise changing control commands such that the modified control commands effect a actuation of the machine tool during which the manufacturing step to which the manufacturing parameter to be changed relates is performed in accordance with the manufacturing parameters changed according to the input data.

Alternatively or additionally, a manufacturing parameter to be changed can be assigned to a group of manufacturing steps. In this case, the above statements relating to a manufacturing parameter to be changed which is assigned to one manufacturing step apply accordingly. For example, the manufacturing parameter to be changed can be assigned to a clamping operation or to a clamping nest.

The parameters extracted from the control commands can specify multiple zero points which are each assigned to at least one manufacturing step in the manufacturing sequence, and the input data can comprise correction data for one zero point of the multiple zero points, the correction data specifying a deviation of an actual position of the zero point in question from an ideal position of the zero point in question defined in the manufacturing sequence. In this case, the generation of modified control commands can comprise changing command parameters of the control commands according to the correction data such that the modified control commands effect a correct actuation of the machine tool according to the manufacturing sequence for the respective actual positions of the zero points. In this manner, it can be made possible for a user to input correction data independently of the start of machining operations. The input data can comprise correction data for a zero point in relation to individual control commands, individual manufacturing steps and/or individual clamping operations or clamping nests.

The correction data can be entered, for example, by a user via a software application (app) on the portable operating device. Alternatively, the correction data can be entered on an operating device of the machine tool. In one embodiment, the correction data can be collected manually by a user of the machine tool, for example by means of corresponding measurement cycles of the machine tool or by collection with an external measurement device, and then entered by the user.

In relation to input data comprising the correction data, it is possible to provide the embodiments explained above in connection with checking whether correction data exist for zero points and determining respective correction data. In particular, the correction data can be stored in a corresponding log file.

The parameters extracted from the control commands can specify the manufacturing steps of the manufacturing sequence, and the input data can comprise a command for scaling a manufacturing step to be scaled in the manufacturing sequence and a scaling factor. In this case, the generation of modified control commands can comprise changing command parameters of control commands which correspond to the manufacturing step to be scaled such that the manufacturing step specifies manufacturing dimensions which are changed according to the changed command parameters and are scaled by the scaling factor relative to original manufacturing dimensions specified by the manufacturing step.

Alternatively or additionally, command parameters which do not specify dimensions, for example command parameters which specify tool parameters, can be changed. For example, an advance and/or a rotation speed can be adjusted. This can be provided for complex machining operations, for example when milling with tangential tool paths and a constant pressure angle. The machining operations can then contain a large number of commands for changing the advance and the rotation speed. In this case, multiple values can be adjusted uniformly.

Alternatively or additionally to the adjustment to other dimensions, scaling within the meaning of the disclosure can comprise an adjustment of the manufacturing sequence to a different material. The above statements on scaling apply analogously here. For instance, it can be made possible to adapt a tool technology also by means of scaling factors.

For example, a user can input the command to scale the manufacturing step to be scaled via a software application (app) on the portable operating device. Alternatively, the input can be made on the machine tool.

In one embodiment, the changing of command parameters of control commands corresponding to the manufacturing step to be scaled comprises the multiplication of all coordinate length dimensions which are defined in connection with the manufacturing step to be scaled, by the scaling factor. For example, the input data can comprise a scaling factor of 120%, and the changing of command parameters of control commands which correspond to the manufacturing step to be scaled can comprise the multiplication of all coordinate length dimensions by the value 1.2. Alternatively or additionally, other command parameters can be changed as coordinate length dimensions. For example, the manufacturing step to be scaled can comprise the production of a bore, and a command parameter which specifies a tool diameter of a tool to be used for the manufacturing step, that is, for example, the diameter of a drill, can be changed.

The additional data can comprise multiple lists which each specify parameters extracted from the control commands. The multiple lists can be stored in one or more files. The multiple lists can each specify parameters extracted from the control commands according to one of the above-described embodiments. The list or one of the multiple lists can specify parameters extracted from the control commands according to several of the above-described embodiments.

The machine tool can be configured to perform machining operations on different clamping pallets, which are each configured to hold multiple blanks to be machined. In this case, the additional data can be pallet-specific. For machining on a first clamping pallet, first additional data can be provided which are specific to the first clamping pallet, and for machining on a second clamping pallet, second additional data can be provided which are specific to the first clamping pallet. For example, the first additional data can comprise information on zero points of clamping nests on the first clamping pallet, and the second additional data can comprise information on zero points of clamping nests on the second clamping pallet. Alternatively or additionally, further pallet-specific data, for example correction data, can be provided.

The additional data can be stored on an external memory unit. The external memory unit can be a server and/or a central shared network resource. The external memory unit and the further external computer unit can be provided in the same physical unit, for example in the same server. The additional data can be provided on the external memory unit in multiple embodiments, for example for the use of the control data on different machine tools. The input data can comprise a selection of additional data and/or a command to change the additional data. Alternatively or additionally, further input data can be received, for example via an input device of the external memory unit and/or the input device of the portable operating device. The further input data can comprise a selection of additional data and/or a command to change the additional data.

Multiple manufacturing sequences and respective control commands and additional data can be provided. The input data can comprise a command for combining individual manufacturing steps to be combined in the multiple manufacturing sequences, and the generation of modified control commands can comprise the combination of control commands corresponding to the manufacturing steps to be combined.

The manufacturing sequence can comprise manufacturing steps relating to only one first zero point and further zero points without respective assigned manufacturing steps. The generation of the control data can comprise the generation of control commands which specify machining operations of the machine tool corresponding to the manufacturing steps of the manufacturing sequence relating to the first zero point and respective machining operations of the machine tool corresponding to the manufacturing steps defined in relation to the first zero point, in relation to each of the further zero points. In this manner, the manufacturing sequence defined in relation to the first zero point can automatically be reproduced respectively in relation to each of the further zero points. For example, a manufacturing data set can be defined in relation to a first zero point of a clamping pallet, and the generation of the control data can comprise the generation of control commands which automatically define the same manufacturing steps for further zero points of the clamping pallet as for the first zero point.

A global zero point can be defined, to which the additional data and, where applicable, further data, for example correction data, relate. For example, multiple zero points of the manufacturing sequence and/or correction data for multiple zero points can be defined in relation to the global zero point. The zero point can be defined, for example, by program cycles on a controller of the machine tool (e.g. CYCLE800 from Siemens) or by the output of calculated zero points in the post-processor. The output of calculated zero points can be useful in the case of extremely short program run times if the calculation of a machine cycle can otherwise take up a large part of the overall program run time. The global zero point can be different from a machine zero point of the machine tool. Such a machine zero point can be adjusted by the manufacturer in order to correct geometric deviations in the machine.

According to the disclosure, a system for controlling a machine tool can be provided, the system comprising a machine tool and at least one of an external computer unit and a portable operating device. The system can be configured to carry out the method for controlling a machine tool.

The embodiments explained in connection with the method for controlling a machine tool can be provided accordingly in the machine tool and/or in the system for controlling a machine tool.

### DESCRIPTION OF EXEMPLARY EMBODIMENTS

Further exemplary embodiments are explained in more detail below with reference to figures of a drawing. In the figures:

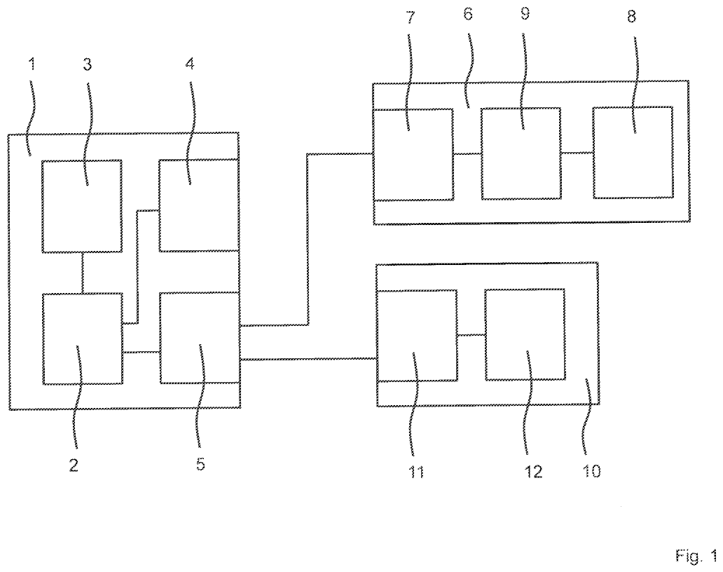

FIG. 1 shows a schematic diagram of a system for controlling a machine tool;

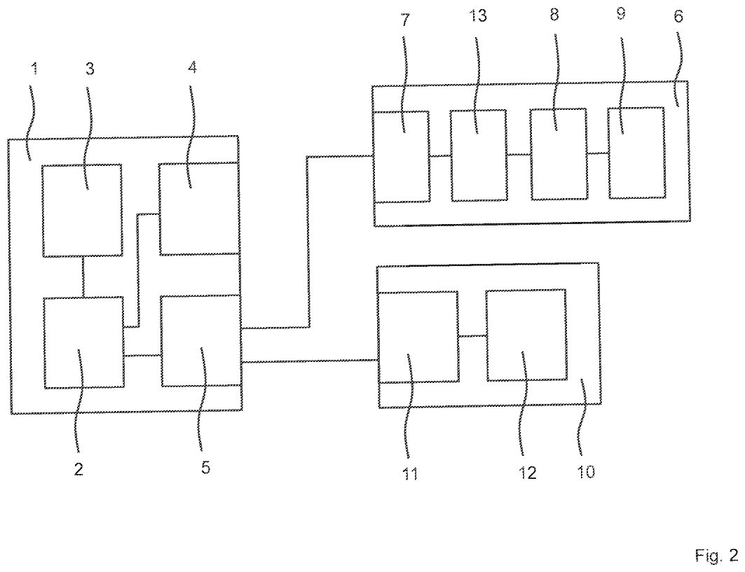

FIG. 2 shows a schematic diagram of another system for controlling a machine tool;

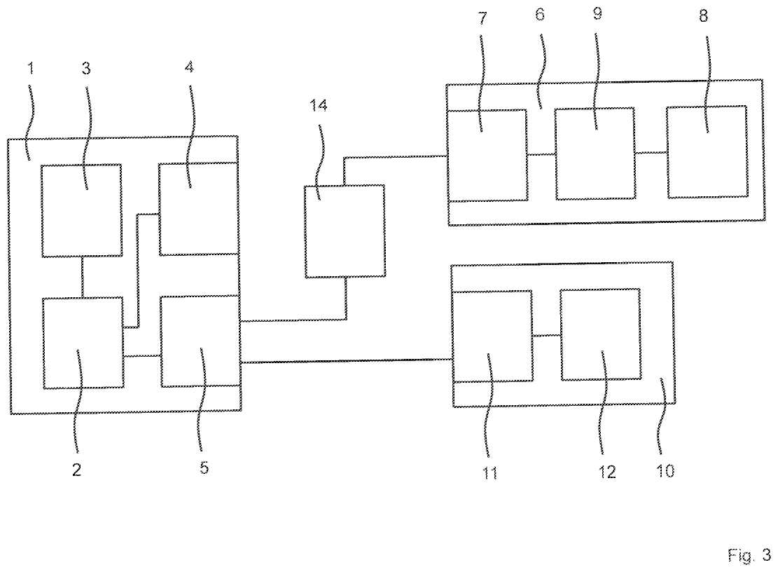

FIG. 3 shows a schematic diagram of a further system for controlling a machine tool; and

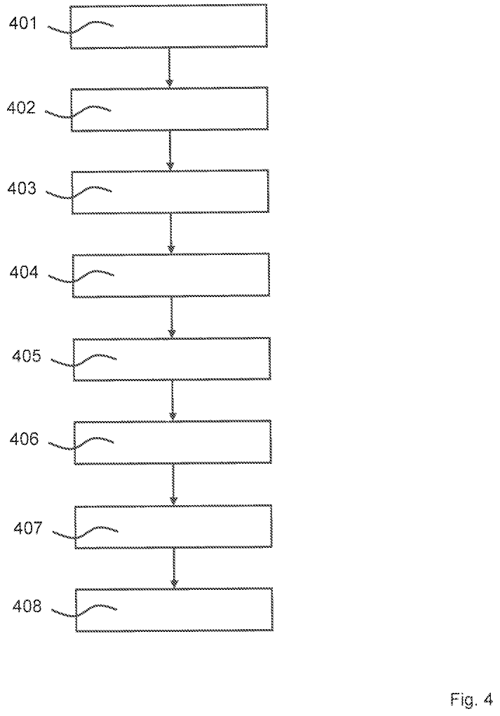

FIG. 4 shows a schematic flow diagram of a method for controlling a machine tool.

FIG. 1 shows a schematic diagram of a system for controlling a machine tool 1. The machine tool 1 comprises a control unit 2, a memory unit 3, an input device 4 and a receiving unit 5.

A wireless data link to an external computer unit 6 is provided via the receiving unit 5. To this end, the external computer unit 6 has a transmitting unit 7. The external computer unit 6 is provided as a computer (PC) in the embodiment shown. The external computer unit 6 further comprises a CAM environment 8 and a post-processor 9. The CAM environment 8 is configured to create a manufacturing data set in the form of a CAM file, and the post-processor 9 is configured to generate an NC program from the CAM file.

A wireless data link to a portable operating device 10 with a transmitting unit 11 is also provided via the receiving unit 5 of the machine tool 1. In the embodiment shown, the portable operating device 10 is a smartphone. A software application (app) 12 for controlling the machine tool 1 is provided in the portable operating device 10. The software application 12 is configured to receive user inputs on the portable operating device 10 and, using the user inputs, to send input data via the transmitting unit 11 to the machine tool 1.

FIG. 2 shows a schematic diagram of another system for controlling a machine tool. In contrast with the system according to FIG. 1, the external computer unit 6 of the system shown in FIG. 2 has an add-on module 13 which is configured to extract additional data from the NC program generated by the post-processor 9.

FIG. 3 shows a schematic diagram of another system for controlling a machine tool. In comparison with the system according to FIG. 1, the system shown in FIG. 3 has a further external computer unit 14. In the embodiment shown, the further external computer unit 14 is a server system which is connected for data communication to the machine tool 1 and the external computer unit 6. For example, the machine tool 1, the external computer unit 6 and the further external computer unit can be connected via a wired local network (LAN) and/or a wireless local network (WLAN).

An embodiment of a method for controlling a machine tool is described below with reference to

FIG. 4. In the embodiment shown, the method is carried out in a system according to FIG. 1. In alternative embodiments, a method for controlling a machine tool can be carried out in systems according to FIGS. 2 and 3. In this case, the method explained in connection with FIG. 4 can be used accordingly. In particular, method steps explained in connection with FIG. 4, which are carried out in or by system components according to FIG. 1, are carried out in embodiments of the method in or by corresponding system components according to one of the FIGS. 2 and 3.

FIG. 4 shows a schematic flow diagram of a method for controlling a machine tool. In a first step 401, a machine tool 1 is provided. Then, in step 402, a manufacturing sequence is provided in an external computer unit 6. The manufacturing sequence is provided as a manufacturing data set in the form of a CAM file by means of a CAM environment 8 in the external computer unit 6. The manufacturing sequence comprises multiple manufacturing steps defined in the CAM file; at least one tool and one tool path are defined for each manufacturing step.

In a step 403, an NC program is created in the external computer unit 6 by means of a post-processor 9, said NC program containing control commands which specify machining operations of the machine tool 1 corresponding to the manufacturing steps of the manufacturing sequence, and the machine tool 1 is configured to convert the control commands into the machining operations. The post-processor 9 is configured to extract additional data from the control commands in a further step 404. The additional data comprise at least one list which specifies parameters extracted from the control commands.

In alternative embodiments, the additional data are not extracted from the control commands by the post-processor 9. The extraction of the additional data in step 404 can take place for example by the CAM environment 8, a corresponding module in a control device 2 of the machine tool 1 to be controlled, or in a further external computer device 14. As a further alternative, an add-on module 13 of the external computer unit 6 can extract the additional data from the control commands.

In step 405, control data, which comprise the control commands and the additional data, are provided in the control unit 2 of the machine tool 1 to be controlled. The generation of the control data from the control commands and the additional data can take place, for example, in the external computer unit 6, and the control data can be provided via a transmitting unit 7 of the external computer unit 6 to a receiving unit 5 of the machine tool 1 in the control unit 2. Alternatively, the control commands and the additional data can be transferred from the external computer unit 6 to the machine tool, and the control data can be generated therefrom in the control unit 2. As a further alternative, the control commands can be transferred from the external computer unit 6 to the machine tool, and the control unit 2 can generate the additional data and generate the control data from the control commands and the additional data.

Subsequently, in step 406, input data are received in the control unit 2, the input data specifying a user input. Input data can be received from the input device 4 of the machine tool and/or via the software application 12 of the portable operating device 10.

In step 407, modified control commands are generated from the control commands in the control unit 2 in accordance with the additional data and the input data. The machine tool 1 is then actuated by the control unit 2 by means of the modified control commands in step 408.

In alternative embodiments, the machine tool can be controlled without the external computer unit 6 and/or without the portable operating device 10. In such embodiments, the functions explained in connection with the external computer unit 6 and/or in connection with the portable operating device 10 can be provided in the machine tool 1.

According to the disclosure, a user or setter of a machine tool 1 can be assisted in the setup and monitoring of a machine tool program which controls machining operations according to a manufacturing sequence using control commands. At the same time, necessary adjustments can be reduced when providing the manufacturing sequence by means of programming. This can prevent the work required being shifted from the setter to a programmer. According to designs, the amount of work required by a programmer for tasks in programming multiple clamping operations can be reduced.

To this end, multiple part-designs or modules can be provided, which build on one another. If programming with CAM software or a CAM environment, these modules can be inserted into the program by a post-processor. If programming on a graphical interface of the machine tool, the modules can be added by programmed cycles and programs in the controller or control unit. Embodiments are described below in connection with a CAM module with a post-processor. The described embodiments can apply correspondingly in connection with a controller or control unit of the machine tool or a direct implementation in a CAM module without an adapted post-processor.

In one embodiment, the post-processor analyses the programmed tool paths. Some of the information which is needed can already be present in the tool paths, for example the tool used, the machining order and the coordinate system used. Other parameters can be defined by the

CAM programmer additionally according to a certain schema. The additionally required information can be defined depending on the functional scope of the CAM module. If user extensions are supported by the CAM module, they can be used to implement setting of the additional parameters via a graphical user interface of the CAM module. Alternatively or additionally, corresponding keywords can be added, for example in a comments field or a designation of the tool path.

The post-processor generates an NC program, in which main and sub-programs or a single main program can be generated, and lists as additional data for controlling the main program.

One of the lists can comprise all the machining steps to switch these on or off. One of the lists can comprise the assignment of all the tools to the respective machining steps. One list can comprise correction data for each individual machining operation. One list can comprise the tool technology data for each machining operation. The lists can be output in one or more files, for example, if the memory or processor of the machine tool does not process complete lists and/or to make it easier to process the data.

One function which can function without further changes by the setter is an automatic resumption following a program interruption. The NC program logs the started and completed machining steps using counters and loops. If the program sequence is interrupted by the user, for example because a tool must be changed or because measurements must be carried out on the workpiece during setup, the setter can also change the tool in the spindle or move the machine. To meet the need for bringing the program and the machine manually back to the same state as before the interruption or for carrying out a restart of the program, it can be determined using the counters, when the program resumes, that the program was not fully executed previously, and an output can be generated which comprises a query whether a restart of the program or a continuation from the old position is desired. If the setter wishes to continue from the old position, the program searches in the tool list for the tool used for the last started machining operation, selects it in the machine tool, and then starts the last machining operation again. The variable values for the currently started machining operation and the completed machining operation can be stored during the program sequence such that the values also remain stored if the emergency off switch is operated or if there are power cuts. This allows machining to be continued on the machine within a short time. The current status of the machining can also be displayed in an app on a portable operating device.

Another function which can function without a change by the setter is the use of only one zero point. In contrast to a conventional programming method, the CAM programmer can in this case also define a global zero point to which all the other zero points relate. Alternatively, a global zero point can already be defined in the CAM module. The post-processor can convert the CAM file or the CAM program such that all the other zero points and coordinate systems are calculated relative to the global zero point. The program can then offset different corrections against each other. The setter thus only has to manage one zero point. This also allows corrections according to the embodiments described below. In addition, advantages can result for the use of machine tools which are connected to a central pallet management system, if in this case only the zero point of the pallet and, where necessary, also an offset is transferred from a master pallet.

A further function which can function without a change by the setter is the automatic calibration of clamping nests. For this, the machine tool can have a measurement sensor and corresponding measurement cycles. At the start of the program, measurement points for the measurement sensor can be defined. Calibration can take place in measurement cycles integrated in the CAM module or via simple machining operations present in any CAM system, for example drilling cycles. By means of a keyword or a setting in a user extension, the post-processor can recognise that a measurement cycle is for determining the nest position and generate the necessary program code for calibrating the clamping nests.

If the program is started and measurement points for determining the nest position are present, the program can first check whether there is already a log file for this program. If a log file exists, old correction values can automatically be used according to the existing log file, and the correction data can be read in from the log file for this purpose. If the setter wishes to recalibrate the position, he can delete the existing log file and restart the program.

If no log file has been found, the nest positions can be calibrated and the measurement values can be stored in a log file. The deviations of the real positions of the clamping nests from the geometrically ideal (theoretical) positions of the clamping nests in the CAM file are then stored in the log file. The use of a global zero point and the calculation of the displacements needed for the machining then allow the position of the clamping nest to be corrected automatically without the setter having to correct the position manually in the NC program. In this case, the actual program is not changed, and therefore maintenance and management can be simplified. If a new version of a program is generated without there being any changes to the real positions of the clamping nests, immediate use of the new program can be made possible, since all the relevant deviations are known and can be stored in the machine tool. It can thereby be made possible to recreate the entire program and replace it on the machine without the need for manual insertion or copying over to retain previous corrections which the setter has already made.

For further functions, it can be necessary for the user to edit lists. This can be done manually or in a guided manner via the software application on the portable operating device or the input device of the machine tool. With guided editing, automatic calculation and display of manufacturing steps according to clamping positions and nests can be made possible.

It can be made possible for machining operations or manufacturing steps to be switched on and/or off by the setter. Fast setup of the program on the machine can thus be made possible.

For example, it is possible for only one machining operation to be carried out initially. This can be corrected, if needed for tool corrections, carried out again and then switched off. The procedure can continue analogously with a subsequent machining operation or a subsequent manufacturing step. In addition, it can be made possible for whole clamping nests to be deactivated via the software, that is, on the machine tool or by means of the application software. It is thus possible for only one first nest to be set up initially, although the same tool would actually perform machining operations on other nests.

If multiple machining operations are performed with the same tool, it is known to retrieve a tool change command in the programming only before the first machining operation or the first manufacturing step. If the first machining operation or the first machining step is deactivated and only a subsequent machining step is to be carried out, it can be necessary to change in the correct tool first. According to the disclosure, the tool needed for the current machining operation can be read out of the tool list according to an automatic resumption. If the tool currently changed into the machine tool does not correspond to the tool needed, the tool change commands needed can automatically be retrieved and then the machining can be carried out.

If whole nests have been switched off, for example because a batch has finished and workpieces are no longer present for all nests, the fastest possible machining can be desired. In this case, it is known for the CAM programmer or the setter to define how far the tool should be withdrawn before the nest machining operation. In the known procedure, it must be noted for the skipping of parts of a program that all the provided free movements are also skipped thereby. In this case, the machine can move directly to the next point and thus through other clamping devices. To avoid this, it is known for the machine tool to move to a safe position after each machining operation. This can result in longer cycle times.

According to the disclosure, it can be made possible for the programmer to define a safety plane for each machining operation in the CAM module. Such a parameter is known per se. In contrast with known methods, the interpretation of the parameter described below is provided according to the disclosure by the post-processor. If there is no parameter for the safety plane in the CAM module, it can be made possible for this to be defined, for example via a user extension or via keywords in comments or in the machining operation name. After executing a switched-on machining operation, the NC program can search for the next switched-on machining operation. In the process, each safety plane of the switched-off machining operations can be checked and the highest value in each case can be stored. Movement to this highest value can then take place to avoid a collision. If there are shaft rotations between the machining operations, a current shaft position can be queried and the rotation executed by the shortest route. If the angle differs only within a narrow range (e.g. ±0.5°), in which a tolerance can be set via the post-processor, the execution of a rotation can be omitted. Time can be saved thereby.

To ensure correct compliance with safety planes, it is known to provide an NC program with jump labels at multiple locations so that tool changes are carried out and all safety planes and rotations are executed correctly. This can be made more difficult by complex programs. To avoid the risk of a collision, it can therefore be provided in known methods for the entire program to be allowed to run without all the manufacturing steps being necessary.

If the machine tool has a device for breakage monitoring of the tools, an activation, for example by the programmer or the setter, of the tool breakage monitoring for individual machining operations can be made possible. In this case, the machine tool checks whether the tool is broken before and after the machining operation in question. If a tool breakage is established, the nest in which the tool is broken can be deactivated and a matching tool can be changed in. This makes it possible for machining to continue. In conjunction with the functions performed in relation to the safety planes and the skipping of deactivated machining operations, the machine tool can thus work longer without a user intervention. This allows the operation of automated shifts without user interventions and with a high level of safety. According to the disclosure, it can be made possible to finish machining workpieces in the other nests when a tool breakage occurs in one nest.

For each machining operation, a fine correction can be stored, for example by the setter. Moreover, it can be made possible to store corrections per clamping nest and shaft position. The corrections per nest and for each machining operation can be set via the app. The app can calculate the values for the fine displacement per machining operation and per nest and angular position so that only the sum of the corrections is stored in the position list. The starting values for the calculation can likewise be stored in the position list. This can make it possible to reset changes to originally programmed values with only one command. This can make it possible to make the corrections without previously making all the said calculations for all the shafts and to take the angular position into account as well. The use of the app can make it possible to make corrections “in the tool direction” without taking into account additional rotations. With manual editing, it is possible for shafts or signs to get mixed up. In addition to the corrections “in the tool direction”, a correction of the clamping nest can also be provided. This can be necessary, for example, if measurement positions on the clamping nests are not produced precisely. In this case, the deviation can be specified once per nest and then automatically calculated for the respective rotations of the nests.

It can be made possible for the cut data to be changed, for example by the setter, via the app for each machining operation. This can be done using both absolute values and relative factors. The cut data for the machining operation can be loaded from the list and then used during machining, for example by the app and/or the control device. The original cut data which the CAM programmer has selected remain in the file. It can thus be made possible for changes to be undone at any time, for example with the aid of the app. In the app, different cut data can be stored for the same machining operation. This can make it possible to select the cut data quickly at a later point. For instance, it can be made possible to use the same CAM program for different materials.

If the machine tool uses multiple pallets, the post-processor can be configured such that the NC program uses dedicated lists for each pallet. In addition, a unique machine number can also be defined and used. This can make it possible to store the real displacements of the individual nests for each clamping tower and to retrieve them when the corresponding pallet is used. Deviations from a combination of a machine with a pallet can thus be stored unambiguously and corrected automatically. These data can be created and managed by the app. If the files are not present at the start of the program, the program can automatically generate copies of the files from the main program and start calibrating the nests.

For the manufacture of similar components in variants, that is, components in which only a few features differ from one another (for example, components with different bore diameters), it can be made possible to create a program for all variants by means of the CAM module. User extensions, comments or names in the machining operations can be used to define different variants. The variants can be evaluated by the post-processor and stored in the position list. The app can be configured to read out this variant information and display it to the user, in a simplified manner if necessary. It can thus be made possible for the user, for example the setter, to select a variant for manufacture. In multiple clamping systems in which more than one workpiece can be machined simultaneously, it can be made possible to define different variants for each clamping nest.

It can be provided for corresponding files to be stored on a central shared network resource, for example on a server. This can make it possible to configure multiple orders in advance. According to the disclosure, parts of a manufacturing control station software can thus be replaced to actuate multiple machines. If a method according to the disclosure is started on a machine tool, a machine number and a pallet number can be read out, and manufacture can take place in preselected nests and/or in preselected variants.

It can be provided for multiple manufacturing sequences or programs to be combined to form a new, combined manufacturing sequence or a combined program, for example by means of the app. In this case, for example for zero point clamping systems with fixed positions, a different program can be executed for each zero point clamping system. Lists of the individual programs can then be set, for example by the app, such that the corresponding nests are activated or deactivated. In addition, a new program can be generated, for example by the app, which uses the corresponding lists and sub-programs of the original programs without changing the original programs.

A log function for logging data can be provided, which can be activated, for example by the programmer or the setter, for example via the app or in the CAM module. With the log function activated, data relating to a machining operation can be logged in a log file. The app can be configured for evaluating the log file. For example, start and end times, results of tool breakage monitoring and other data which can be made available by the controller and/or the machine tool can be output here. The app can be configured to prepare data for the setter and, for example, create statistics on the data.

To relieve the CAM programmer when programming multiple clamping systems, it can be provided for only one manufacturing sequence or machining operation to be programmed in relation to one zero point in the CAM module. If this machining operation is also to be carried out at other positions, it can be provided for only a dummy machining operation to be created instead of a copy of the machining operation to define a machining order. The post-processor can then automatically generate the necessary copies. The programming effort can be reduced thereby.

Programming can thus be provided for multiple zero points or nests without all the nests being programmed individually in turn or individual program parts being combined after programming to form a main program or a manufacturing sequence with corresponding displacements. Furthermore, if there are changes to the manufacturing sequence, it is no longer necessary to carry out the same changes for all the zero points or clamping nests or to transfer changes in sub-programs to the main program manually. According to the disclosure, it can be made possible to generate an executable NC program without further interventions. If no changes have been made to positions of clamping nests, it can be made possible for the old NC program to be overwritten with the new one; previous corrections are retained, and normal production operation can start immediately.

It can be provided for further modified control commands for a subsequent actuation of the machine tool corresponding to the further modified control commands to be generated during actuation of the machine tool corresponding to the modified control commands. Thus, in contrast with a conventional type of programming of a machine tool, it can be made possible for the next sequence of the program (e.g. the next pallet in a machine tool with a pallet-changing device) to be configured even while the active program is still being processed. In particular, this can be made possible in that all the data which change between different program sequences are kept in lists and are not in a main program.

Modified control commands can be generated for the application of a manufacturing sequence to another machine tool. For example, the use of lists can make it possible to convert control data or a posted program simply for another machine. If the control data or the program have been generated for example for a horizontal milling machine, the control data or the program can be converted with the aid of the app in order to be processed on a vertical milling machine. Here, not only can the coordinates be swapped, but also the rotation axes can be adjusted accordingly. Furthermore, special features of a particular milling machine can be taken into account, for example rotation axes of −180°/+180° or 0°/360°.

Complex individual parts such as those from tool- and die-making can be programmed with an oversize. The program can be run through once and the critical dimensions can be measured subsequently. The same program can then be run through again without the oversize. Manufacturing with or without an oversize can take place by changing a command parameter corresponding to the oversize or to the absence of an oversize during generation of the modified control commands. For example, a tool diameter can be changed to achieve an oversize or the absence of an oversize.

The features disclosed in the above description, the claims, and the drawings can be of significance for the implementation of the different embodiments both individually and in any combination.

1. A method for controlling a machine tool, comprising:
providing a machine tool;
providing a manufacturing sequence comprising multiple manufacturing steps, at least one tool and one tool path being defined for each manufacturing step;
generating control data, the control data comprising:
control commands, the control commands specifying machining operations of the machine tool according to the manufacturing steps of the manufacturing sequence, and the machine tool being configured to convert the control commands into the machining operations, and
additional data, the additional data comprising at least one list which specifies parameters extracted from the control commands;
providing the control data in a control unit of the machine tool;
receiving input data in the control unit, the input data specifying a user input;
generating modified control commands by means of the control unit, the modified control commands being generated from the control commands in accordance with the additional data and the input data; and
actuating the machine tool by the control device by means of the modified control commands.

2. The method according to claim 1, wherein the manufacturing sequence is provided as a manufacturing data set in an external computer unit.

3. The method according to claim 2, wherein the control commands are generated in the external computer unit from the manufacturing data set.

4. The method according to claim 3, wherein the additional data are generated in the external computer unit.

5. The method according to claim 1, wherein the input data are received in the control unit from an input device of the machine tool.

6. The method according to claim 1, wherein the input data are received in the control unit from an input device of a portable operating device via a transmitting unit of the portable operating device and a receiving unit of the machine tool.

7. The method according to claim 1, wherein
the parameters extracted from the control commands specify the manufacturing steps of the manufacturing sequence;
the input data comprise a command to start machining operations by the machine tool after a previous interruption of machining operations according to the control commands; and
the generation of modified control commands comprises the following:
the deletion of control commands which correspond to manufacturing steps of the manufacturing sequence which were completed before the interruption of machining operations, and
at least one of the addition of a control command and the addition of a command parameter for a control command such that, when machining operations start, machining takes place as if no previous interruption of machining operations has taken place.

8. The method according to claim 1, wherein
the parameters extracted from the control commands specify multiple zero points which are each assigned to at least one manufacturing step of the manufacturing sequence;
the input data comprise a command to start machining operations by the machine tool; and
the generation of modified control commands comprises the following:
checking whether correction data exist for each of the zero points, the correction data specifying a deviation of an actual position of the zero point in question from an ideal position of the zero point in question defined in the manufacturing sequence;
if no correction data exist for the zero points, determining correction data for each zero point; and
changing command parameters of the control commands according to the correction data such that the modified control commands effect a correct actuation of the machine tool according to the manufacturing sequence for the respective actual positions of the zero points.

9. The method according to claim 1, wherein
the parameters extracted from the control commands specify the manufacturing steps of the manufacturing sequence;
the input data comprise a command for deactivating a manufacturing step to be deactivated of the manufacturing sequence; and
the generation of modified control commands comprises the deletion of control commands which correspond to the manufacturing step to be deactivated.

10. The method according to claim 1, wherein
the parameters extracted from the control commands specify the manufacturing steps of the manufacturing sequence and functions associated with the respective manufacturing steps;
the input data comprise a command for deactivating a function to be deactivated of a manufacturing step of the manufacturing sequence; and
the generation of modified control commands comprises the deletion of control commands which correspond to the function to be deactivated of the manufacturing step.

11. The method according to claim 1, wherein
the parameters extracted from the control commands specify the manufacturing steps of the manufacturing sequence and manufacturing parameters associated with the respective manufacturing steps;
the input data comprise a command for changing a manufacturing parameter to be changed of a manufacturing step of the manufacturing sequence; and
the generation of modified control commands comprises changing control commands such that the modified control commands effect an actuation of the machine tool in which the manufacturing step to which the manufacturing parameter to be changed relates is performed in accordance with the manufacturing parameter changed according to the input data.

12. The method according to claim 1, wherein
the parameters extracted from the control commands specify multiple zero points which are each assigned to at least one manufacturing step of the manufacturing sequence;
the input data comprise correction data for one zero point of the multiple zero points, the correction data specifying a deviation of an actual position of the zero point in question from an ideal position of the zero point in question defined in the manufacturing sequence; and
the generation of modified control commands comprises changing command parameters of the control commands according to the correction data such that the modified control commands effect a correct actuation of the machine tool according to the manufacturing sequence for the respective actual positions of the zero points.

13. The method according to claim 1, wherein
the parameters extracted from the control commands specify the manufacturing steps of the manufacturing sequence;
the input data comprise a command for scaling a manufacturing step to be scaled in the manufacturing sequence and a scaling factor; and
the generation of modified control commands comprises changing command parameters of control commands which correspond to the manufacturing step to be scaled such that the manufacturing step specifies changed manufacturing dimensions according to the changed command parameters, which changed manufacturing dimensions and are scaled by the scaling factor relative to original manufacturing dimensions specified by the manufacturing step.

14. The method according to claim 1, wherein the additional data comprise multiple lists which each specify parameters extracted from the control commands.

15. A machine tool, comprising a control device, the control device being configured to
provide control data, the control data comprising:
control commands, the control commands specifying machining operations of the machine tool corresponding to manufacturing steps of a manufacturing sequence, the manufacturing sequence comprising multiple manufacturing steps, and at least one tool and one tool path being defined for each manufacturing step, and the machine tool being configured to convert the control commands into the machining operations, and
additional data, the additional data comprising at least one list which specifies parameters extracted from the control commands;
receive input data which specify a user input;
generate modified control commands from the control commands according to the additional data and the input data; and
actuate the machine tool by means of the modified control commands.
